(19) United States
(12) Patent Application Publication
(10) Pub. No.: US 2008/0157375 A1
(43) Pub. Date: Jul. 3, 2008

(54) Semiconductor device having a metal interconnection and method of fabricating the same

(75) Inventor: Han Choon Lee, Poongnap-dong (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/893,009

(22) Filed: Aug. 13, 2007

(30) Foreign Application Priority Data
Dec. 27, 2006 (KR) 10-2006-0135567
Dec. 27, 2006 (KR) 10-2006-0135771

(51) Int. Cl. H01L 21/4763; H01L 23/48

(52) U.S. Cl. 257/751; 438/643; 257/E21.495; 257/E23.01

(57) ABSTRACT

Disclosed are a semiconductor device and a method for fabricating a metal interconnection of a semiconductor device. The method includes the steps of forming a dielectric layer on a semiconductor substrate including a lower interconnection, forming a trench in the interlayer dielectric layer that exposes the lower interconnection, forming a diffusion barrier in the trench and on the interlayer dielectric layer, forming a copper seed layer on the diffusion barrier, implanting a metal dopant into the copper seed layer, forming a copper metal interconnection on the copper seed layer into which the metal dopant is implanted, and forming an alloy layer from the copper seed layer and the metal dopant.

The present application claims priority under 35 U.S.C. 119 and 35 U.S.C. 365 to Korean Patent Application No. 10-2006-0135567 (filed on Dec. 27, 2006), which is hereby incorporated by reference in its entirety.

### BACKGROUND

The invention relates to a metal interconnection of a semiconductor device and a method of fabricating the same.

As a semiconductor device has become highly integrated and operated at a high speed, a copper interconnection has been rapidly developed. The copper interconnection uses copper that has resistance smaller than aluminum or aluminum alloy, which has been widely utilized as interconnection material in semiconductor devices, and has relatively large resistivity and high electromigration.

As the size of a semiconductor device has been reduced, size reduction of a metal interconnection using copper is required. Also, since the grain size of a copper metal interconnection has also been gradually reduced, current may be concentrated at grain boundaries.

### SUMMARY

Embodiments of the invention provide a metal interconnection of a semiconductor device and a method of fabricating the same, in which a copper seed layer for a copper metal interconnection is deposited and then doped with an aluminum component using an ion implantation method, and a Cu—Al alloy layer is formed through a heat treatment process, so that the reliability of the semiconductor device can be improved.

In order to accomplish the object of the present invention, there is provided a method for fabricating a metal interconnection of a semiconductor device, the method comprising the steps of forming a dielectric layer on a semiconductor substrate including a lower interconnection; forming a trench in the interlayer dielectric layer that exposes the lower interconnection; forming a diffusion barrier in the trench and on the dielectric layer; forming a copper seed layer on the diffusion barrier; implanting a metal dopant into the copper seed layer; forming a copper metal interconnection on the copper seed layer into which the metal dopant is implanted; and forming an alloy layer from the copper seed layer and the metal dopant.

In order to accomplish the object of the present invention, there is provided a semiconductor device having a metal interconnection, comprising a dielectric layer on a semiconductor substrate including a lower interconnection; a trench in the dielectric layer; a diffusion barrier in the trench and on the dielectric layer; an alloy layer on the diffusion barrier; and a copper interconnection on the alloy layer.

### BRIEF DESCRIPTION OF THE DRAWINGS

FIGS. 1 to 6 are sectional views sequentially showing the procedure for fabricating a metal interconnection of a semiconductor device according to an exemplary embodiment of the present invention.

### DETAILED DESCRIPTION OF THE EMBODIMENTS

Hereinafter, a metal interconnection of a semiconductor device and a method of fabricating the same will be described in detail with reference to the accompanying drawings.

FIG. 6 is a sectional view showing a metal interconnection of a semiconductor device according to an exemplary embodiment of the present invention.

Referring to FIG. 6, an interlayer dielectric layer 20 is formed on a semiconductor substrate 10 in which a lower interconnection 15 is formed. The dielectric layer 20 may comprise one or more layers of dielectric materials, such as silicon dioxide (which may be doped with fluorine or boron and/or phosphorous, and/or which may comprise a plasma silane and/or a TEOS-based oxide), silicon nitride (e.g., which may function as an etch stop), silicon rich oxide (SRO), “black diamond” (e.g., an oxide of silicon and carbon (SiCₓO_{y}, where x is generally <1 and y is from about 2 to about 2*(1+x)], which may further comprise hydrogen). In one embodiment, the interlayer dielectric layer 20 comprises a silicon nitride layer, a first silicon oxide layer (e.g., USG), a fluorosilicate glass (FSG), and one or more second silicon oxide layers (e.g., a USG/TEOS bilayer), stacked in succession.

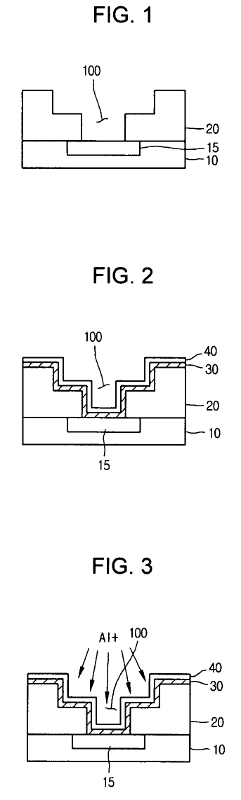

A trench 100 (see, e.g., FIGS. 1-4) that exposes the lower interconnection 15 is formed in the interlayer dielectric layer 20. In the embodiment shown in Figures, trench 100 comprises a “dual damascene” structure (i.e., a trench in the dielectric layer 20, and a via hole in the trench exposing the lower interconnection 15).

A diffusion barrier 30 is formed on the interlayer dielectric layer 20, including in the trench, in order to prevent the diffusion of copper material. Typically, the diffusion barrier 30 comprises TaN or TiN, preferably TaN, and more preferably on an adhesive layer comprising Ti, Ta or a bilayer with another metal thereon such as Ru.

A Cu—Al alloy layer 60 is formed on the diffusion barrier 30, and a copper metal interconnection 70 is formed on the Cu—Al alloy layer 60.

As described above, the Cu—Al alloy layer 60 is formed on the diffusion barrier 30, and the copper metal interconnection 70 is formed thereon, so that adhesive force of an interface between the diffusion barrier 30 and the copper metal interconnection 70 can be improved, thereby improving the reliability of the device.

Hereinafter, a method of fabricating the metal interconnection having the structure as described above in the semiconductor device will be described with reference to FIGS. 1 to 6.

Referring to FIG. 1, the interlayer dielectric layer 20 is formed on the semiconductor substrate 10 in which the lower interconnection 15 is formed, and then the trench 100 (or “dual damascene” trench and via) that exposes the lower interconnection 15 is formed through an etching process (or, in the dual damascene case, two successive photolithography and etching processes, one to define the trench and the other to define the via). For example, the interlayer dielectric layer 20 can include an oxide layer and/or other layers, as described above. Further, the lower interconnection 15 can include material (e.g., a conductor) such as aluminum or copper.

Although not shown in the drawings, a field oxide layer can be formed on or in a field area of the semiconductor substrate 10 in order to define an active area of the semiconductor substrate 10, and source, drain and gate electrodes of a transistor can be formed on or in the active area. Then, a predetermined pattern is formed in the dielectric layer 20 using a dual damascene process, thereby forming the trench 100 (and via) that exposes the lower interconnection 15.

Referring to FIG. 2, the diffusion barrier 30 is formed on the interlayer dielectric layer 20 and in the trench 100 in order to prevent copper, which is subsequently filled in the trench 100, from diffusing into the interlayer dielectric layer 20. For example, the diffusion barrier 30 can include Ta, TaN, TiSiN or TaSiN, and be formed using Physical Vapor Deposition (PVD), Chemical Vapor Deposition (CVD) or Atomic Layer Deposition (ALD).

Then, a copper seed layer 40 is formed on the diffusion barrier 30 along a stepped portion of the diffusion barrier 30 such that the subsequent metal deposition process can be easily performed. For example, the copper seed layer 40 may be formed using the PVD process, the CVD process or the ALD process.

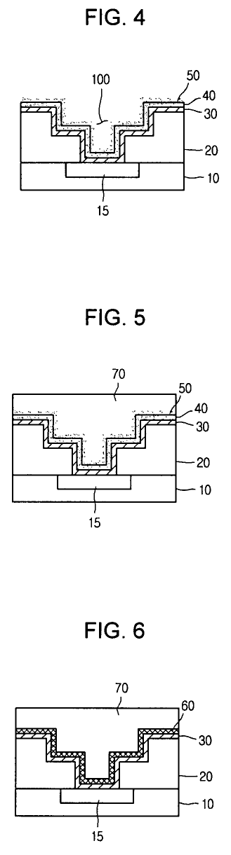

Referring to FIG. 3 and FIG. 4, an aluminum dopant 50 is implanted into the copper seed layer 40 using an ion implantation method. The aluminum dopant 50 can be formed by vaporizing Al₂O₃, sputtering elemental Al or through ionizing Trimethyl Al (TMA), aluminum hydride (Al₂H₆) or an aluminum trihalide (e.g., AlF₃, AlCl₃). For example, according to process conditions of the ion implantation, an energy is 3 KeV to 7 KeV, the amount of implanted ions is 10¹⁵ to 10¹⁶ ion/cm², and a tilt angle is 0°. Accordingly, the aluminum dopant 50 is implanted under the process conditions, so that the aluminum species 50 are uniformly distributed on the copper seed layer 40.

The reasons for implanting aluminum dopants 50 include an ability of aluminum to form a high-density passivation layer such as Al₂O₃, and aluminum has excellent adhesive force, and thus the adhesive force between the copper metal interconnection 70 and the diffusion barrier 30 can be improved in the subsequent process. When the aluminum dopant 50 is implanted into the copper seed layer 40 as described above, some of the aluminum dopant 50 is implanted into the copper sₑe_{d} layer 40 and the remaining is present on the surface of the copper seed layer 40.

Referring to FIG. 5, the copper metal interconnection 70 is formed on the copper seed layer 40 in which the aluminum dopant 50 is implanted, including in the trench 100 in the interlayer dielectric layer 20. For example, the copper metal interconnection 70 can be formed using an Electro Chemical Plating (ECP) method, an electroless plating method or a PVD method.

Referring to FIG. 6, a heat treatment process is performed for the interlayer dielectric layer 20 on which the copper metal interconnection 70 is formed. As the heat treatment process is performed, the aluminum dopant 50 reacts with the copper metal interconnection 70, thereby forming a Cu—Al alloy layer 60 between the diffusion barrier 30 and the copper metal interconnection 70. The aluminum reacts with the copper at an atomic ratio of 1:2, thereby forming Cu₂Al. This is because copper and aluminum have the same crystalline structure and similar lattice constants, and thus Cu₂Al can be easily formed through thermal reaction.

For example, in the heat treatment process, the temperature may be from 100° C. to 300° C., N₂ or other inert gas is injected to prevent oxidation, and/or the process is performed in a vacuum atmosphere of from 10³ torr to 10⁷ torr. In this way, a Cu—Al alloy layer 60 can be formed between the diffusion barrier 30 and the copper metal interconnection 70 through the heat treatment process, so that adhesive force of an interface between the diffusion barrier 30 and the copper metal interconnection 70 can be improved, thereby improving the reliability of the device.

Although not shown in the drawing, the copper metal interconnection 70 can be planarized through a Chemical Mechanical Planarization (CMP) process. In the planarization process for the copper metal interconnection 70, the interlayer dielectric layer 20 or the diffusion barrier 30 can be used as an etching stop layer.

After the diffusion barrier and the copper seed layer are deposited in the trench formed using the damascene or dual damascene pattern, in the present metal interconnection and method of fabricating the same, an aluminum dopant is implanted by an ion implantation process into the copper seed layer, and then a Cu—Al alloy layer is stably formed through a heat treatment process, so that adhesive force between the copper metal interconnection and the diffusion barrier can be improved, thereby improving the reliability of the copper metal interconnection.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a metal interconnection, comprising the steps of:
forming a dielectric layer on a semiconductor substrate, including a lower interconnection;
forming a trench in the dielectric layer that exposes the lower interconnection;
forming a diffusion barrier in the trench on the dielectric layer;
forming a copper seed layer on the diffusion barrier;
implanting a metal dopant into the copper seed layer;
forming a copper metal interconnection on the copper seed layer into which the metal dopants are implanted; and
forming an alloy layer from the copper seed layer and the metal dopant.

2. The method as claimed in claim 1, wherein forming the alloy layer comprises a heat treatment process.

3. The method as claimed in claim 1, wherein the metal dopant comprises aluminum ions.

4. The method as claimed in claim 1, wherein the alloy layer comprises a Cu—Al alloy layer.

5. The method as claimed in claim 3, wherein the aluminum ions are generated from Al₂O₃ or Trimethyl Aluminum (TMA).

6. The method as claimed in claim 1, wherein the metal dopant is implanted with an energy of from 3 KeV to 7 KeV.

7. The method as claimed in claim 1, wherein the metal dopant is implanted in an amount of from 10¹⁵ to 10¹⁶ ion/cm.

8. The method as claimed in claim 1, wherein the alloy layer comprises Cu₂Al.

9. The method as claimed in claim 1, wherein the alloy layer consists essentially of Cu₂Al.

10. The method as claimed in claim 2, wherein the heat treatment process is performed at a temperature of 100° C. to 300° C. and a pressure of from 10⁻³ torr to 10⁻⁷ torr.

11. The method as claimed in claim 2, wherein the heat treatment process further comprises injecting N₂ gas.

12. A semiconductor device having a metal interconnection, comprising:
a dielectric layer on a semiconductor substrate including a lower interconnection;
a trench in the dielectric layer;
a diffusion barrier in the trench and on the interlayer dielectric layer;
an alloy layer on the diffusion barrier; and
a copper interconnection on the alloy layer.

13. The semiconductor device as claimed in claim 12, wherein the alloy layer comprises a Cu—Al alloy layer.

14. The semiconductor device as claimed in claim 12, wherein the alloy layer comprises Cu₂Al.

15. The semiconductor device as claimed in claim 12, wherein the alloy layer consists essentially of Cu₂Al.
